(19) United States
(12) Patent Application Publication
(10) Pub. No.: US 2025/0393299 A1
(43) Pub. Date: Dec. 25, 2025

(54) SEMICONDUCTOR DEVICE INCLUDING AN ACTIVE PATTERN AND A DUMMY STRUCTURE

(71) Applicant: SAMSUNG ELECTRONICS CO., LTD., SUWON-SI (KR)

(72) Inventors: HYUNGJUNE KIM, Suwon-si, Gyeonggi-do (KR); BYUNGYUN KANG, Suwon-si, Gyeonggi-do (KR); DONGGYUN KIM, Suwon-si, Gyeonggi-do (KR); DONGHYUN KIM, Suwon-si, Gyeonggi-do (KR); BYUNG-SUNG KIM, Suwon-si, Gyeonggi-do (KR); SUTAE KIM, Suwon-si, Gyeonggi-do (KR); YOOSEONG KIM, Suwon-si, Gyeonggi-do (KR); DAEHOON PARK, Suwon-si, Gyeonggi-do (KR); SUNGKEUN PARK, Suwon-si, Gyeonggi-do (KR); SUNG HO PARK, Suwon-si, Gyeonggi-do (KR); HAEWANG LEE, Suwon-si, Gyeonggi-do (KR); SUNGWOO JANG, Suwon-si, Gyeonggi-do (KR); JIYOUNG JUNG, Suwon-si, Gyeonggi-do (KR)

(21) Appl. No.: 19/010,778

(22) Filed: Jan. 6, 2025

(30) Foreign Application Priority Data
Jun. 25, 2024 (KR) 10-2024-0083066

(51) Int. Cl. H10D 84/85; H10D 84/01

(52) U.S. Cl. CPC H10D 84/851; H10D 84/0188; H10D 84/856

(57) ABSTRACT

A semiconductor device includes: a first active pattern; a first source/drain pattern disposed on the first active pattern; a second active pattern spaced apart from the first active pattern in a first direction; a second source/drain pattern disposed on the second active pattern; a gate electrode overlapping the first active pattern and extending in a second direction intersecting the first direction; and a dummy structure disposed between the first active pattern and the second active pattern and between the first source/drain pattern and the second source/drain pattern, wherein the dummy structure includes: a first line portion extending in the second direction; a second line portion extending in the second direction and spaced apart from the first line portion in the first direction; and a first connection portion connecting the first line portion and the second line portion to each other.

### CROSS-REFERENCE TO RELATED APPLICATION

This U.S. non-provisional patent application claims priority under 35 U.S.C. § 119 to Korean Patent Application No. 10-2024-0083066, filed on Jun. 25, 2024, the disclosure of which is incorporated by reference herein in its entirety.

### TECHNICAL FIELD

The present inventive concept herein relates to a semiconductor device, and more particularly, to a semiconductor device including an active pattern and a dummy structure.

### DISCUSSION OF THE RELATED ART

Generally, a semiconductor device includes an integrated circuit that includes metal-oxide-semiconductor field effect transistors (MOSFETs). As a size and a design rule of a semiconductor device are gradually reduced, scaling down of the metal-oxide-semiconductor field effect transistors is also gradually accelerated. However, as the metal-oxide-semiconductor field effect transistors are scaled down, operation characteristics of the semiconductor device may deteriorate. Accordingly, research is being conducted into various methods to address the limitations arising from increased integration and scaling down of a semiconductor device and to develop a semiconductor device with increased performance.

### SUMMARY

According to embodiments of the present inventive concept, a semiconductor device includes: a first active pattern; a first source/drain pattern disposed on the first active pattern; a second active pattern spaced apart from the first active pattern in a first direction; a second source/drain pattern disposed on the second active pattern; a gate electrode overlapping the first active pattern and extending in a second direction intersecting the first direction; and a dummy structure disposed between the first active pattern and the second active pattern and between the first source/drain pattern and the second source/drain pattern, wherein the dummy structure includes: a first line portion extending in the second direction; a second line portion extending in the second direction and spaced apart from the first line portion in the first direction; and a first connection portion connecting the first line portion and the second line portion to each other.

According to embodiments of the present inventive concept, a semiconductor device includes: a first active pattern; a second active pattern spaced apart from the first active pattern in a first direction; a dummy structure disposed between the first active pattern and the second active pattern; a gate electrode disposed on the first active pattern and extending in a second direction intersecting the first direction; a dummy active pattern spaced apart from the first active pattern and the second active pattern in the second direction; and a first dummy line and a second dummy line disposed on the dummy active pattern and extending in the second direction, wherein the first dummy line overlaps the gate electrode in the second direction, and the second dummy line overlaps the dummy structure in the second direction.

According to embodiments of the present inventive concept, a semiconductor device includes: a first active pattern; a first source/drain pattern disposed on the first active pattern; a second active pattern spaced apart from the first active pattern in a first direction; a second source/drain pattern disposed on the second active pattern; a dummy active pattern spaced apart from the first active pattern and the second active pattern in a second direction, wherein the second direction intersects the first direction; a dummy structure disposed between the first active pattern and the second active pattern, and between the first source/drain pattern and the second source/drain pattern; a gate electrode disposed on the first active pattern and extending in the second direction; and a first dummy line and a second dummy line disposed on the dummy active pattern and extending in the second direction, wherein the dummy structure includes: a first line portion extending in the second direction; a second line portion extending in the second direction and spaced apart from the first line portion in the first direction; and a connection portion connecting the first line portion and the second line portion to each other, wherein the first dummy line overlaps the gate electrode in the second direction, and the second dummy line overlaps the first line portion in the second direction.

### BRIEF DESCRIPTION OF THE FIGURES

The accompanying drawings are included to provide a further understanding of the present inventive concept, and are incorporated in and constitute a part of this specification. The drawings illustrate embodiments of the present inventive concept and, together with the description, serve to illustrate features and elements of the present inventive concept. In the drawings:

FIG. 1A is a plan view of a semiconductor device according to embodiments of the present inventive concept;

FIG. 1B is a cross-sectional view taken along line A-A′ of FIG. 1A;

FIG. 1C is a cross-sectional view taken along line B-B′ of FIG. 1A;

FIG. 1D is an enlarged view of region C of FIG. 1A;

FIG. 1E is a cross-sectional view taken along line D-D′ of FIG. 1D;

FIG. 1F is a cross-sectional view taken along line E-E′ of FIG. 1D;

FIG. 1G is a cross-sectional view taken along line F-F′ of FIG. 1D;

FIGS. 2A, 2B, 3A, 3B, and 4 are diagrams for describing a method for manufacturing a semiconductor device according to FIGS. 1A to 1G;

FIG. 5 is a plan view of a semiconductor device according to embodiments of the present inventive concept;

FIG. 6A is a plan view of a semiconductor device according to embodiments of the present inventive concept;

FIG. 6B is an enlarged view of region G of FIG. 6A;

FIG. 6C is a cross-sectional view taken along line H-H′ of FIG. 6B;

FIG. 6D is a cross-sectional view taken along line I-I′ of FIG. 6B;

FIG. 6E is a cross-sectional view taken along line J-J′ of FIG. 6B;

FIG. 6F is a cross-sectional view taken along line K-K′ of FIG. 6B;

FIGS. 7 and 8 are cross-sectional views for describing a method for manufacturing a semiconductor device according to FIGS. 6A to 6F;

FIG. 9 is a plan view of a semiconductor device according to embodiments of the present inventive concept; and

FIG. 10 is a cross-sectional view of a semiconductor device according to embodiments of the present inventive concept.

### DETAILED DESCRIPTION OF THE EMBODIMENTS

Embodiments of the present inventive concept describe a semiconductor device with improved electrical characteristics and reliability. The semiconductor device may include dummy structure positioned between the active patterns of the semiconductor device. The dummy structure may mitigate performance degradation often associated with high-density integration in semiconductor manufacturing.

According to embodiments of the present inventive concept, the dummy structure includes at least two line portions extending in a direction perpendicular to the active patterns, and a connection portion linking them. This specific configuration helps improve the device's performance and reliability by managing stress and preventing defects during manufacturing.

Further, embodiments of the present inventive concept focus on the integration of dummy lines and gate electrodes to optimize the performance and reliability of the semiconductor device. The arrangement of these structures helps to reduce the risk of defects and improves overall stability.

It is to be understood that in the following description that singular expressions and/or elements include plural expressions and/or elements unless the context clearly dictates otherwise.

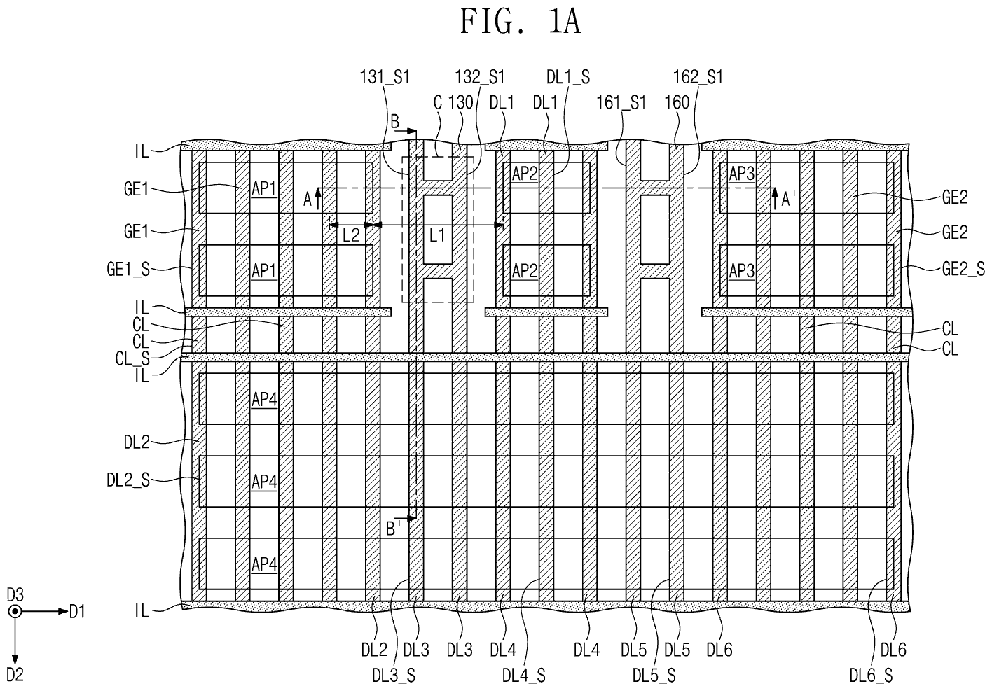

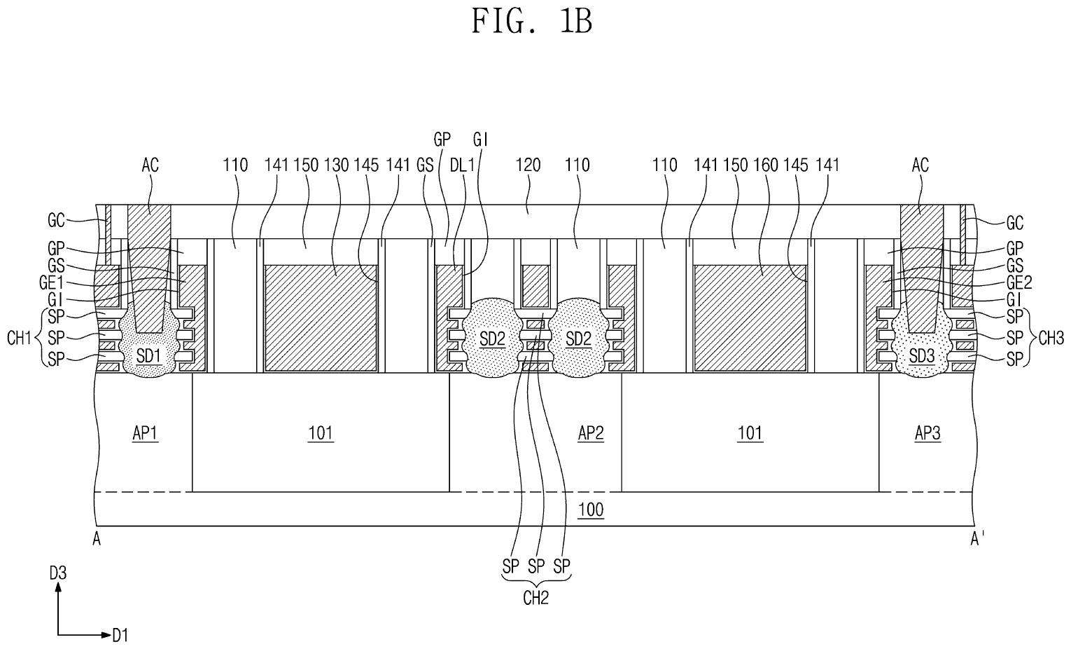

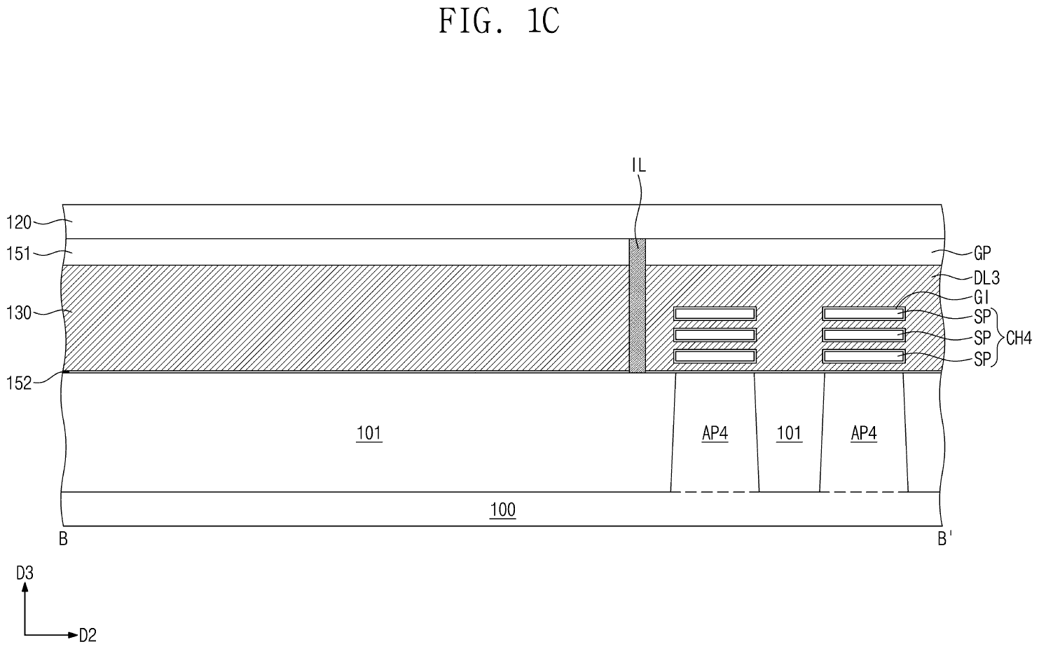

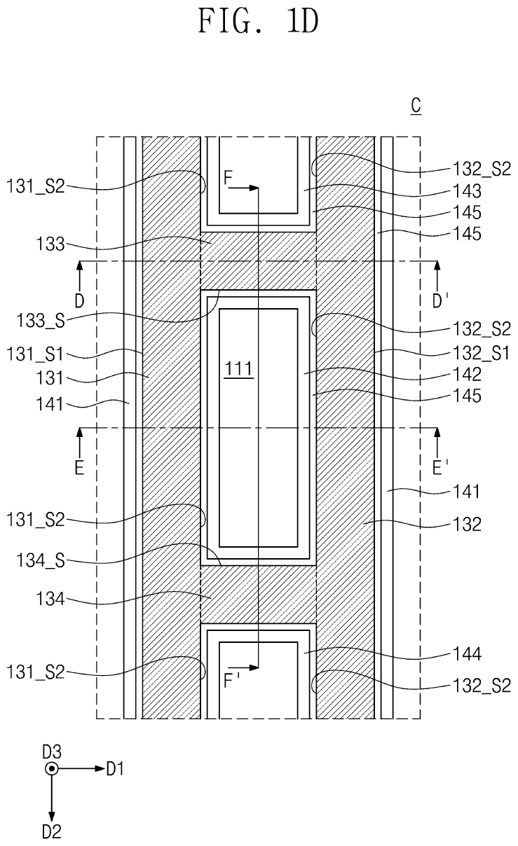

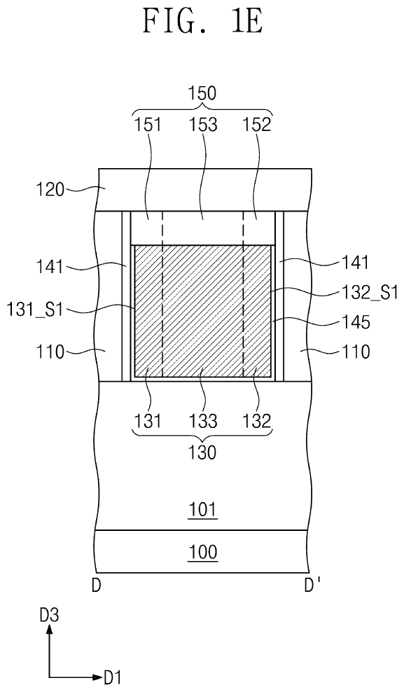

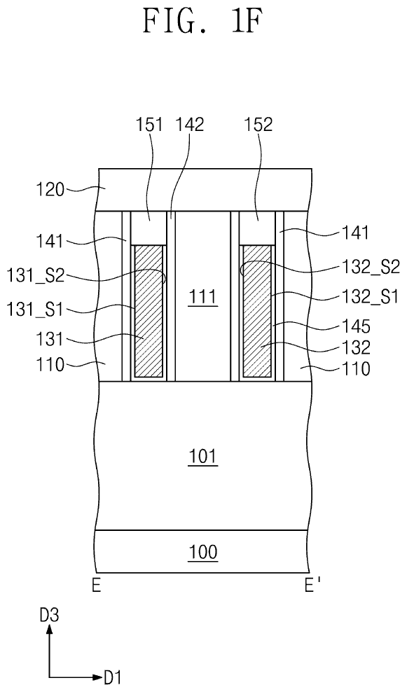

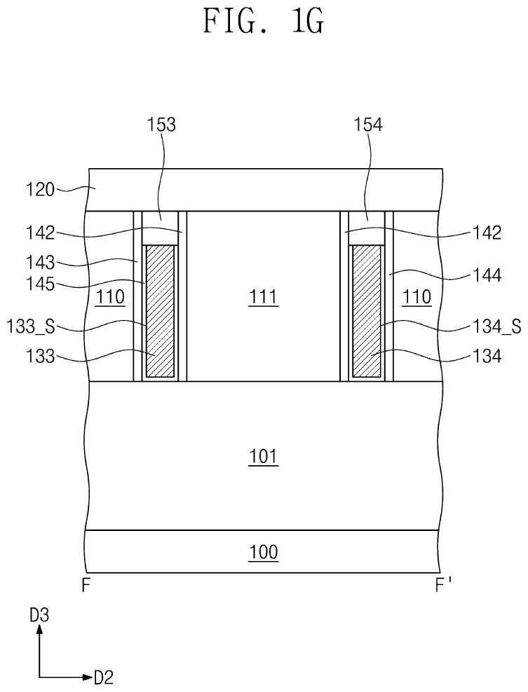

FIG. 1A is a plan view of a semiconductor device according to embodiments of the present inventive concept. FIG. 1B is a cross-sectional view taken along line A-A′ of FIG. 1A. FIG. 1C is a cross-sectional view taken along line B-B′ of FIG. 1A. FIG. 1D is an enlarged view of region C of FIG. 1A. FIG. 1E is a cross-sectional view taken along line D-D′ of FIG. 1D. FIG. 1F is a cross-sectional view taken along line E-E′ of FIG. 1D. FIG. 1G is a cross-sectional view taken along line F-F′ of FIG. 1D.

Referring to FIGS. 1A, 1B, and 1C, the semiconductor device may include a substrate 100. The substrate 100 may be, for example, a semiconductor substrate, an insulator substrate, a silicon-on-insulator (SOI) substrate, or a germanium-on-insulator (GOI) substrate. The semiconductor substrate may include, for example, silicon, germanium, silicon-germanium, GaP, or GaAs.

The substrate 100 may have a shape of a plate, square, or rectangle extending along a plane extending in a first direction D1 and a second direction D2. The first direction D1 and the second direction D2 may intersect each other. For example, the first direction D1 and the second direction D2 may be horizontal directions perpendicular to each other.

The substrate 100 may include first active patterns AP1, second active patterns AP2, third active patterns AP3, and fourth active patterns AP4. The first to fourth active patterns AP1, AP2, AP3, and AP4 may extend in the first direction D1. The first to fourth active patterns AP1, AP2, AP3, and AP4 may be portions protruding in a third direction D3 of the substrate 100. The third direction D3 may intersect the first direction D1 and the second direction D2. For example, the third direction D3 may be a vertical direction that is perpendicular to the first direction D1 and the second direction D2.

The first active pattern AP1 and the second active pattern AP2 may be spaced apart from each other in the first direction D1. The second active pattern AP2 and the third active pattern AP3 may be spaced apart from each other in the first direction D1. The second active pattern AP2 may be disposed between the first active pattern AP1 and the third active pattern AP3.

The fourth active pattern AP4 may be spaced apart from each of the first to third active patterns AP1, AP2, and AP3 in the second direction D2. The fourth active pattern AP4 may overlap the first to third active patterns AP1, AP2, and AP3 in the second direction D2. In the present disclosure, the wording “component A and component B overlap in X direction” means that there is a line extending in the X direction and intersecting the components A and B.

A length of the fourth active pattern AP4 in the first direction D1 may be greater than a length of each of the first to third active patterns AP1, AP2, and AP3 in the first direction D1. A length of the fourth active pattern AP4 in the first direction D1 may be greater than a sum of lengths of the first to third active patterns AP1, AP2, and AP3 in the first direction D1.

According to embodiments of the present inventive concept, each of the first and third active patterns AP1 and AP3 may be a cell active pattern, and each of the second and fourth active patterns AP2 and AP4 may be a dummy active pattern.

An element isolation film 101 may be provided on the substrate 100. The element isolation film 101 may at least partially surround the first to fourth active patterns AP1, AP2, AP3, and AP4. The element isolation film 101 may include an insulating material. For example, the element isolation film 101 may include an oxide.

First source/drain patterns SD1 may be provided on the first active pattern AP1. Second source/drain patterns SD2 may be provided on the second active pattern AP2. Third source/drain patterns SD3 may be provided on the third active pattern AP3. Fourth source/drain patterns may be provided on the fourth active pattern AP4.

The source/drain patterns SD1, SD2, and SD3 may be epitaxial patterns which are formed through a selective epitaxial growth (SEG) process. The first to fourth source/drain patterns SD1, SD2, and SD3 may include a semiconductor material. For example, the first to fourth source/drain patterns SD1, SD2, and SD3 may include at least one of silicon (Si), silicon-germanium (SiGe), or germanium (Ge). The first to fourth source/drain patterns SD1, SD2, and SD3 may be doped with an impurity.

First channel structures CH1, which overlaps the first active pattern AP1 in the third direction D3, may be provided. Second channel structures CH2, which overlaps the second active pattern AP2 in the third direction D3, may be provided. Third channel structures CH3, which overlaps the third active pattern AP3 in the third direction D3, may be provided. Fourth channel structures CH4, which overlaps the fourth active pattern AP4 in the third direction D3, may be provided.

The channel structures CH1, CH2, CH3, and CH4 may each include semiconductor patterns SP overlapping each other in the third direction D3. According to embodiments of the present inventive concept, the semiconductor patterns SP may include silicon (Si). For example, the semiconductor patterns SP may include crystalline silicon. According to embodiments of the present inventive concept, the semiconductor patterns SP may include silicon-germanium (SiGe).

First gate electrodes GE1 may be provided on the first active patterns AP1. The first gate electrode GE1 may overlap the first active pattern AP1 in the third direction D3. The first gate electrode GE1 may overlap the first channel structure CH1 in the third direction D3. The first gate electrode GE1 and the semiconductor patterns SP of the first channel structure CH1 may constitute a three-dimensional field effect transistor (for example, MBCFET or GAAFET).

Second gate electrodes GE2 may be provided on the third active patterns AP3. The second gate electrode GE2 may overlap the third active pattern AP3 in the third direction D3. The second gate electrode GE2 may overlap the third channel structure CH3 in the third direction D3.

First dummy lines DL1 may be provided on the second active patterns AP2. The first dummy line DL1 may overlap the second active pattern AP2 in the third direction D3. The first dummy line DL1 may overlap the second channel structure CH2 in the third direction D3.

Second dummy lines DL2, third dummy lines DL3, fourth dummy lines DL4, fifth dummy lines DL5, and sixth dummy lines DL6 may be provided on the fourth active patterns AP4. The second to sixth dummy lines DL2, DL3, DL4, DL5, and DL6 may overlap the fourth active pattern AP4 in the third direction D3. The second to sixth dummy lines DL2, DL3, DL4, DL5, and DL6 may each overlap the fourth channel structure CH4 in the third direction D3. The second to sixth dummy lines DL2, DL3, DL4, DL5, and DL6 may be sequentially arranged along the first direction D1.

The first and second gate electrodes GE1 and GE2, and the first to sixth dummy lines DL1, DL2, DL3, DL4, DL5, and DL6 may include the same conductive material as one another. Each of the first and second gate electrodes GE1 and GE2 may be a cell gate electrode, and each of the first to sixth dummy lines DL1, DL2, DL3, DL4, DL5, and DL6 may be a dummy gate electrode. The first to sixth dummy lines DL1, DL2, DL3, DL4, DL5, and DL6 may be electrically floated.

The second dummy line DL2 may overlap the first gate electrode GE1 in the second direction D2. A sidewall DL2_S of the second dummy line DL2 and a sidewall GE1_S of the first gate electrode GE1 may extend parallel to the second direction D2. According to embodiments of the present inventive concept, the sidewall DL2_S of the second dummy line DL2 and the sidewall GE1_S of the first gate electrode GE1 may be arranged on a straight line extending in the second direction D2. For example, a sidewall DL2_S of the second dummy line DL2 and a sidewall GE1_S of the first gate electrode GE1 may be aligned with each other in second direction D2.

The third dummy line DL3 may overlap a first line portion 131 or second line portion 132 of a first dummy structure 130 to be described later in the second direction D2. A sidewall DL3_S of the third dummy line DL3 may be parallel to the second direction D2. According to embodiments of the present inventive concept, a first sidewall 131_S1 of the first line portion 131 of the first dummy structure 130 and the sidewall DL3_S of the third dummy line DL3 may be arranged on a straight line extending in the second direction D2. For example, the first sidewall 131_S1 of the first line portion 131 of the first dummy structure 130 and the sidewall DL3_S of the third dummy line DL3 may be aligned with each other in the second direction D2. According to embodiments of the present inventive concept, a first sidewall 132_S1 of the second line portion 132 of the first dummy structure 130 and the sidewall DL3_S of the third dummy line DL3 may be arranged on a straight line extending in the second direction D2. For example, the first sidewall 132_S1 of the second line portion 132 of the first dummy structure 130 and the sidewall DL3_S of the third dummy line DL3 may be aligned with each other in the second direction D2.

The fourth dummy line DL4 may overlap the first dummy line DL1 in the second direction D2. A sidewall DL4_S of the fourth dummy line DL4 and a sidewall DL1_S of the first dummy line DL1 may be parallel to the second direction D2. According to embodiments of the present inventive concept, the sidewall DL4_S of the fourth dummy line DL4 and the sidewall DL1_S of the first dummy line DL1 may be arranged on a straight line extending in the second direction D2. For example, the sidewall DL4_S of the fourth dummy line DL4 and the sidewall DL1_S of the first dummy line DL1 may be aligned with each other in the second direction D2.

The fifth dummy line DL5 may overlap a first line portion 161 or second line portion 162 of a second dummy structure 160 to be described later in the second direction D2. A sidewall DL5_S of the fifth dummy line DL5 may be parallel to the second direction D2. According to embodiments of the present inventive concept, a first sidewall 161_S1 of the first line portion 161 of the second dummy structure 160 and the sidewall DL5_S of the fifth dummy line DL5 may be arranged on a straight line extending in the second direction D2. For example, the first sidewall 161_S1 of the first line portion 161 of the second dummy structure 160 and the sidewall DL5_S of the fifth dummy line DL5 may be aligned with each other in the second direction D2. According to embodiments of the present inventive concept, a first sidewall 162_S1 of the second line portion 162 of the second dummy structure 160 and the sidewall DL5_S of the fifth dummy line DL5 (e.g., another fifth dummy line) may be arranged on a straight line extending in the second direction D2. For example, the first sidewall 162_S1 of the second line portion 162 of the second dummy structure 160 and the sidewall DL5_S of the fifth dummy line DL5 may be aligned with each other in the second direction D2.

The sixth dummy line DL6 may overlap the second gate electrode GE2 in the second direction D2. A sidewall DL6_S of the sixth dummy line DL6 and a sidewall GE2_S of the second gate electrode GE2 may be parallel to the second direction D2. According to embodiments of the present inventive concept, the sidewall DL6_S of the sixth dummy line DL6 and the sidewall GE2_S of the second gate electrode GE2 may be arranged on a straight line extending in the second direction D2. For example, the sidewall DL6_S of the sixth dummy line DL6 and the sidewall GE2_S of the second gate electrode GE2 may be aligned with each other in the second direction D2.

Connection lines CL may be provided. The connection lines CL may include the connection line CL disposed between the first gate electrode GE1 and the second dummy line DL2, the connection line CL disposed between the first dummy line DL1 and the fourth dummy line DL4, and the connection line CL disposed between the second gate electrode GE2 and the sixth dummy line DL6. The connection line CL disposed between the first gate electrode GE1 and the second dummy line DL2 may overlap the first gate electrode GE1 and the second dummy line DL2 in the second direction D2. The connection line CL disposed between the first dummy line DL1 and the fourth dummy line DL4 may overlap the first dummy line DL1 and the fourth dummy line DL4 in the second direction D2. The connection line CL disposed between the second gate electrode GE2 and the sixth dummy line DL6 may overlap the second gate electrode GE2 and the sixth dummy line DL6 in the second direction D2. According to embodiments, a sidewall CL_S of the connection line CL disposed between the first gate electrode GE1 and the second dummy line DL2, the sidewall GE1_S of the first gate electrode GE1, and the sidewall DL2_S of the second dummy line DL2 may be arranged on a straight line extending in the second direction D2. For example, the sidewall CL_S of the connection line CL disposed between the first gate electrode GE1 and the second dummy line DL2, the sidewall GE1_S of the first gate electrode GE1, and the sidewall DL2_S of the second dummy line DL2 may be aligned with each other in the second direction D2.

A distance, in the first direction D1, between a center of the first gate electrode GE1 disposed closest to the first dummy line DL1 and a center of the first dummy line DL1 disposed closest to the first gate electrode GE1 may be defined as a first distance L1. A pitch between the first gate electrodes GE1 in the first direction D1 may be defined as a second distance L2. The first distance L1 may be a multiple of the second distance L2. In an embodiments of the present inventive concept, the first distance L1 may be a multiple of a distance between a center of the second dummy line DL2 and a center of the third dummy line DL3. In embodiments of the present inventive concept, the distance between the center of the second dummy line DL2 and the center of the third dummy line DL3 may be equal to the second distance L2.

A first dummy structure 130 and a second dummy structure 160 may be provided. The first dummy structure 130 and the second dummy structure 160 may overlap a fourth active pattern AP4 in the second direction D2.

The first dummy structure 130 may be provided between the first active pattern AP1 and the second active pattern AP2, between the first source/drain pattern SD1 and the second source/drain pattern SD2, and between the first gate electrode GE1 and the first dummy line DL1. The first dummy structure 130 may include the same conductive material as the first and second gate electrodes GE1 and GE2, and the first to sixth dummy lines DL1, DL2, DL3, DL4, DL5, and DL6. The first dummy structure 130 may be electrically floated.

The second dummy structure 160 may be provided between the second active pattern AP2 and the third active pattern AP3, between the second source/drain pattern SD2 and the third source/drain pattern SD3, and between the first dummy line DL1 and the second gate electrode GE2. The second dummy structure 160 may include the same conductive material as the first and second gate electrodes GE1 and GE2, the first to sixth dummy lines DL1, DL2, DL3, DL4, DL5, and DL6, and the first dummy structure 130. The second dummy structure 160 may be electrically floated. The first and second dummy structures 130 and 160 may be a dummy gate structure.

Isolation insulating films IL may be provided. The isolation insulating films IL may extend in the first direction D1. The first and second gate electrodes GE1 and GE2, and the first to sixth dummy lines DL1, DL2, DL3, DL4, DL5, and DL6 may be each disposed between two isolation insulating films IL adjacent in the second direction D2. The isolation insulating film IL may be in contact with the element isolation film 101. The isolation insulating film IL may include an insulating material. For example, the isolation insulating film IL may include a nitride.

The isolation insulating film IL may be provided between the first gate electrode GE1 and the connection line CL. The first gate electrode GE1 and the connection line CL may be spaced apart in the second direction D2 by the isolation insulating film IL. The isolation insulating film IL may be provided between the first dummy line DL1 and the connection line CL. The isolation insulating film IL may be provided between the second gate electrode GE2 and the connection line CL. The isolation insulating film IL may be provided between the second dummy line DL2 and the connection line CL, between the third dummy line DL3 and the first dummy structure 130, between the fourth dummy line DL4 and the connection line CL, between the fifth dummy line DL5 and the second dummy structure 160, and between the sixth dummy line DL6 and the connection line CL.

According to embodiments of the present inventive concept, the isolation insulating film IL might not be provided between the first gate electrode GE1 and the connection line CL, and the first gate electrode GE1 and the connection line CL may constitute an integrated cell gate electrode. According to embodiments of the present inventive concept, the isolation insulating film IL might not be provided between the first dummy line DL1 and the connection line CL, and the first dummy line DL1 and the connection line CL may constitute an integrated dummy gate electrode.

A gate insulating film GI may be provided. The gate insulating film GI may be in contact with each of the first and second gate electrodes GE1 and GE2, the connection lines CL, and the first to sixth dummy lines DL1, DL2, DL3, DL4, DL5, and DL6. The gate insulating film GI may include an insulating material. For example, the gate insulating film GI may include an oxide.

Gate spacers GS may be provided. A pair of gate spacers GS may be disposed on two sides of each of the first and second gate electrodes GE1 and GE2, and the first to sixth dummy lines DL1, DL2, DL3, DL4, DL5, and DL6. The gate spacers GS may extend in the second direction D2. Upper surfaces of the gate spacers GS may be substantially coplanar with an upper surface of a first interlayer insulating layer 110 to be described later. The gate spacers GS may include an insulating material.

Gate capping patterns GP may be provided. The gate capping patterns GP may be provided on the first and second gate electrodes GE1 and GE2, the connection lines CL, and the first to sixth dummy lines DL1, DL2, DL3, DL4, DL5, and DL6. The gate capping pattern GP may extend in the second direction D2. The gate capping pattern GP may include an insulating material.

Outer spacers 141 may be provided. A pair of outer spacers 141 may be disposed on two sides of the first dummy structure 130 and/or two sides of the second dummy structure 160. The outer spacers 141 may extend in the second direction D2. Lower surfaces of the outer spacers 141 may be disposed on an upper surface of the element isolation film 101. For example, the lower surfaces of the outer spacers 141 may be in contact with the upper surface of the element isolation film 101. The outer spacer 141 may include the same insulating material as the gate spacer GS.

Dummy insulating films 145 may be provided. The dummy insulating film 145 may be disposed on the first dummy structure 130 and/or the second dummy structure 160. For example, the dummy insulating film 145 may be in contact with the first dummy structure 130 and/or the second dummy structure 160. The dummy insulating film 145 may include the same insulating material as the gate insulating film GI.

Dummy capping patterns 150 may be provided. The dummy capping pattern 150 may be provided on the first dummy structure 130 and/or second dummy structure 160. A shape of the dummy capping pattern 150 in a plan view may be the same as or similar to a shape of the first dummy structure 130 and/or second dummy structure 160 in a plan view. The dummy capping pattern 150 may include the same insulating material as the gate capping pattern GP.

A first interlayer insulating layer 110 may be provided. The first interlayer insulating layer 110 may be provided on the source/drain patterns SD1, SD2, and SD3, the gate spacers GS, and the outer spacers 141. A second interlayer insulating layer 120 may be provided on the first interlayer insulating layer 110. The second interlayer insulating layer 120 may be provided on the gate spacers GS, the gate capping patterns GP, the outer spacers 141, and the dummy capping patterns 150. The first and second interlayer insulating layers 110 and 120 may include an insulating material. For example, each of the first and second interlayer insulating layers 110 and 120 may include an oxide.

Active contacts AC penetrating the first and second interlayer insulating layers 110 and 120 may be provided. The active contact AC may be electrically connected to the first source/drain pattern SD1 and/or the third source/drain pattern SD3. The active contact AC may include a conductive material.

Gate contacts GC may be provided. At least one of the first gate electrodes GE1 may be electrically connected to the gate contact GC. At least one of the second gate electrodes GE2 may be electrically connected to the gate contact GC. The gate contact GC may penetrate the second interlayer insulating layer 120 and the gate capping pattern GP, and may contact the first gate electrodes GE1 and the second gate electrodes GE2. The gate contact GC may include a conductive material.

Referring to FIGS. 1D, 1E, 1F, and 1G, the first dummy structure 130 may include a first line portion 131, a second line portion 132, a first connection portion 133, and a second connection portion 134. The first line portion 131 and the second line portion 132 may extend in the second direction D2. The first connection portion 133 and the second connection portion 134 may each connect the first line portion 131 and the second line portion 132 to each other. The first connection portion 133 and the second connection portion 134 may extend in the first direction D1. The first connection portion 133 and the second connection portion 134 may be spaced apart from each other in the second direction D2. The first line portion 131 and the second line portion 132 may be spaced apart from each other in the first direction D1. Similar to the first dummy structure 130, the second dummy structure 160 (see FIGS. 1A and 1B) may include a first line portion, a second line portion, a first connection portion, and a second connection portion.

The first line portion 131 may include the first sidewall 131_S1 and second sidewalls 131_S2. The second sidewalls 131_S2 of the first line portion 131 may be opposed to the first sidewall 131_S1. For example, each of the first connection portion 133 and the second connection portion 134 may be disposed between a pair of adjacent second sidewalls 131_S2 of the first line portion 131. The second line portion 132 may include the first sidewall 132_S1 and second sidewalls 132_S2. The second sidewalls 132_S2 of the second line portion 132 may be opposed to the first sidewall 132_S1. For example, each of the first connection portion 133 and the second connection portion 134 may be disposed between a pair of adjacent second sidewalls 132_S2 of the second line portion 132. The sidewalls 131_S1, 131_S2, 132_S1, and 132_S2 of the first and second line portions 131 and 132 may extend in the second direction D2. The second sidewall 131_S2 of the first line portion 131 may face the second sidewall 132_S2 of the second line portion 132.

Sidewalls 133_S of the first connection portion 133 may be each connected to the second sidewall 131_S2 of the first line portion 131 and the second sidewall 132_S2 of the second line portion 132. Sidewalls 134_S of the second connection portion 134 may be each connected to the second sidewall 131_S2 of the first line portion 131 and the second sidewall 132_S2 of the second line portion 132. The sidewalls 133_S and 134_S of the first and second connection portions 133 and 134 may extend in the first direction D1.

A first inner spacer 142 surrounded by the first dummy structure 130 may be provided. The first inner spacer 142 may be surrounded by the formation of the first line portion 131, the second line portion 132, the first connection portion 133, and the second connection portion 134. The first inner spacer 142 may be disposed between the first and second line portions 131 and 132 in the first direction D1, and between the first and second connection portions 133 and 134 in the second direction D2.

The first inner spacer 142 may include first portions extending in the first direction D1 and second portions extending in the second direction D2. The first portions of the first inner spacer 142 may be spaced apart from each other in the second direction D2. The second portions of the first inner spacer 142 may be spaced apart from each other in the first direction D1. The second portions of the first inner spacer 142 may connect the first portions to each other. For example, the first inner spacer 142 may have a rectangular annular shape.

A second inner spacer 143 disposed between the first and second line portions 131 and 132, and between the first connection portion 133 and the isolation insulating film IL (see FIG. 1A) may be provided. A third inner spacer 144 disposed between the first and second line portions 131 and 132, and between the second connection portion 134 and the isolation insulating film IL (see FIG. 1A) may be provided. The first inner spacer 142, the first connection portion 133, and the second connection portion 134 may be arranged between the second and third inner spacers 143 and 144.

The first to third inner spacers 142, 143, and 144 may include the same insulating material as the gate spacer GS and the outer spacer 141. Lower surfaces of the outer spacer 141 and the first to third inner spacers 142, 143, and 144 may be disposed on an upper surface of the element isolation film 101. For example, the lower surfaces of the outer spacer 141 and the first to third inner spacers 142, 143, and 144 may be in contact with the upper surface of the element isolation film 101.

An inner insulating film 111 surrounded by the first inner spacer 142 may be provided. The inner insulating film 111 may be disposed between the first portions of the first inner spacer 142, and between the second portions of the first inner spacer 142. The inner insulating film 111 may include the same insulating material as the first interlayer insulating layer 110. The inner insulating film 111 may be disposed on the upper surface of the element isolation film 101, a sidewall of the first inner spacer 142, and a lower surface of the second interlayer insulating layer 120. For example, the inner insulating film 111 may be in contact with the upper surface of the element isolation film 101, the sidewall of the first inner spacer 142, and the lower surface of the second interlayer insulating layer 120.

The dummy insulating film 145 may be provided between the outer spacer 141 and the first dummy structure 130. The outer spacer 141 may be spaced apart from the first dummy structure 130 by the dummy insulating film 145. The dummy insulating film 145 may be provided between the first inner spacer 142 and the first dummy structure 130, between the second inner spacer 143 and the first dummy structure 130, and between the third inner spacer 144 and the first dummy structure 130. Each of the first to third inner spacers 142, 143, and 144 may be spaced apart from the first dummy structure 130 by the dummy insulating film 145. The dummy insulating film 145 may be provided between the element isolation film 101 and the first dummy structure 130. The element isolation film 101 and the first dummy structure 130 may be spaced apart from each other by the dummy insulating film 145.

The dummy insulating film 145 may be in contact with the first and second sidewalls 131_S1, 131_S2, 132_S1, and 132_S2 of the first and second line portions 131 and 132 and the sidewalls 133_S and 134_S of the first and second connection portions 133 and 134.

The dummy capping pattern 150 may include a first portion 151 overlapping the first line portion 131 in the third direction D3, a second portion 152 overlapping the second line portion 132 in the third direction D3, a third portion 153 overlapping the first connection portion 133 in the third direction D3, and a fourth portion 154 overlapping the second connection portion 134 in the third direction D3.

The first and second portions 151 and 152 of the dummy capping pattern 150 may extend in the second direction D2. The third and fourth portions 153 and 154 of the dummy capping pattern 150 may extend in the first direction D1. The third and fourth portions 153 and 154 of the dummy capping pattern 150 may connect the first and second portions 151 and 152 to each other. The dummy capping pattern 150 may surround the first inner spacer 142.

In a semiconductor device according to embodiments of the present inventive concept, since the dummy structures 130 and 160 include the connection portions 133 and 134, the line portions 131 and 132 may be supported by the connection portions 133 and 134. Accordingly, a leaning phenomenon of the dummy structures 130 and 160 may be prevented or suppressed in a process of forming the dummy structures 130 and 160.

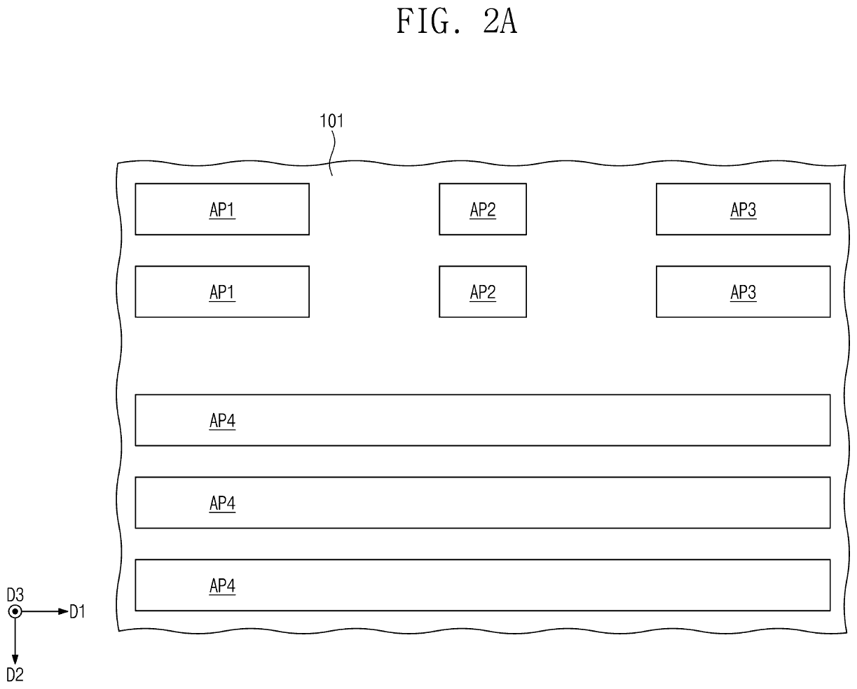

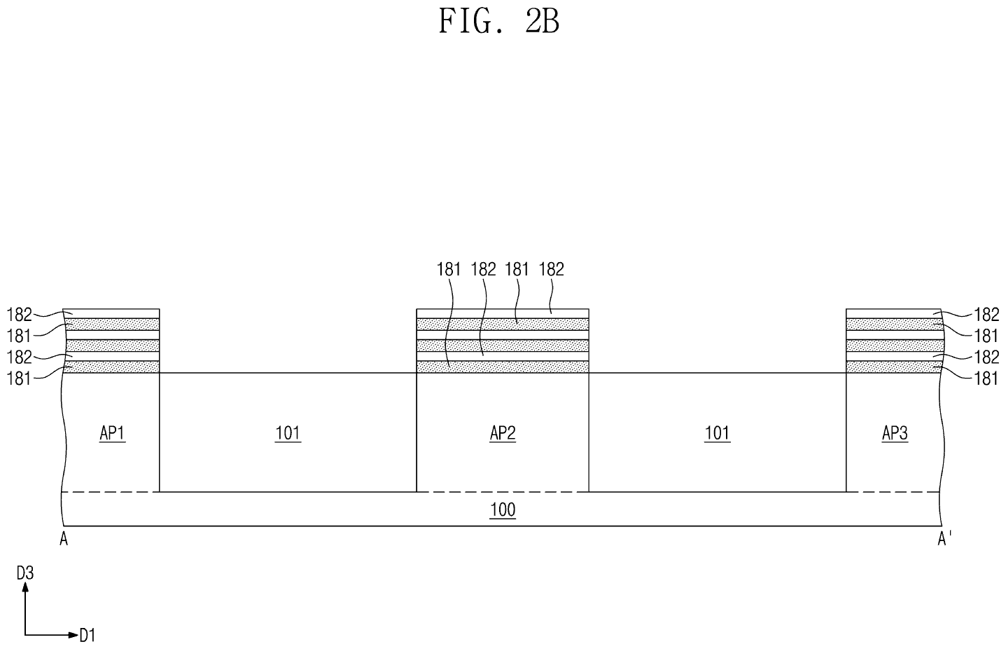

FIGS. 2A, 2B, 3A, 3B, and 4 are diagrams for describing a method for manufacturing a semiconductor device according to FIGS. 1A to 1G.

Referring to FIGS. 2A and 2B, first active patterns AP1, second active patterns AP2, third active patterns AP3, fourth active patterns AP4, sacrificial films 181, and semiconductor films 182 may be formed. Forming the first active patterns AP1, the second active patterns AP2, the third active patterns AP3, the fourth active patterns AP4, the sacrificial films 181, and the semiconductor films 182 may include alternately forming preliminary sacrificial films and preliminary semiconductor films on a substrate 100, and patterning the preliminary sacrificial films, the preliminary semiconductor films, and the substrate 100.

The sacrificial films 181 may be formed by patterning the preliminary sacrificial films. The semiconductor films 182 may be formed by patterning the preliminary semiconductor films. The first to fourth active patterns AP1, AP2, AP3, and AP4 may be formed by patterning the substrate 100.

The sacrificial film 181 may include a material having etching selectivity with respect to the semiconductor film 182. For example, the sacrificial film 181 may include silicon-germanium, and the semiconductor film 182 may include silicon. An element isolation film 101 may be formed.

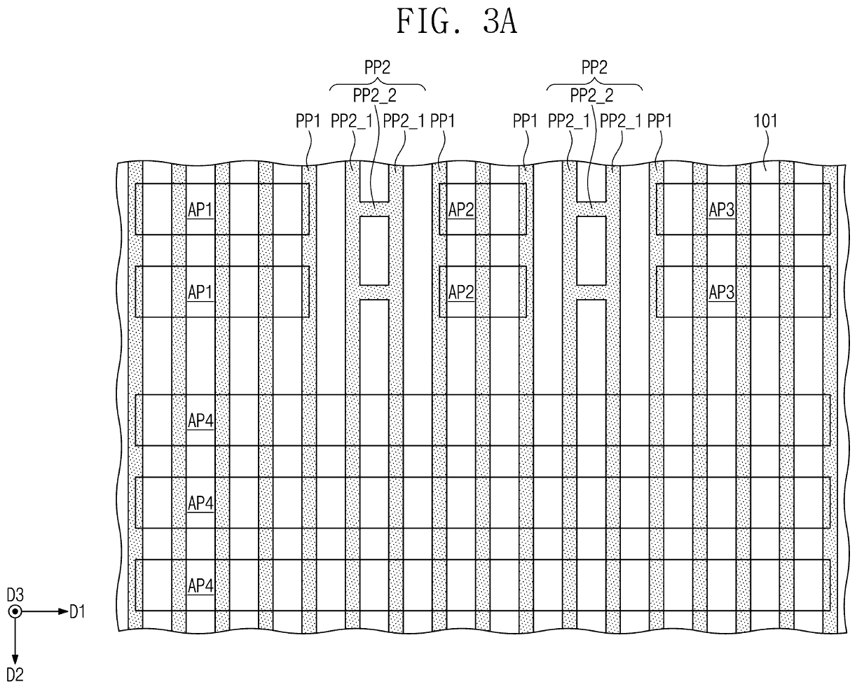

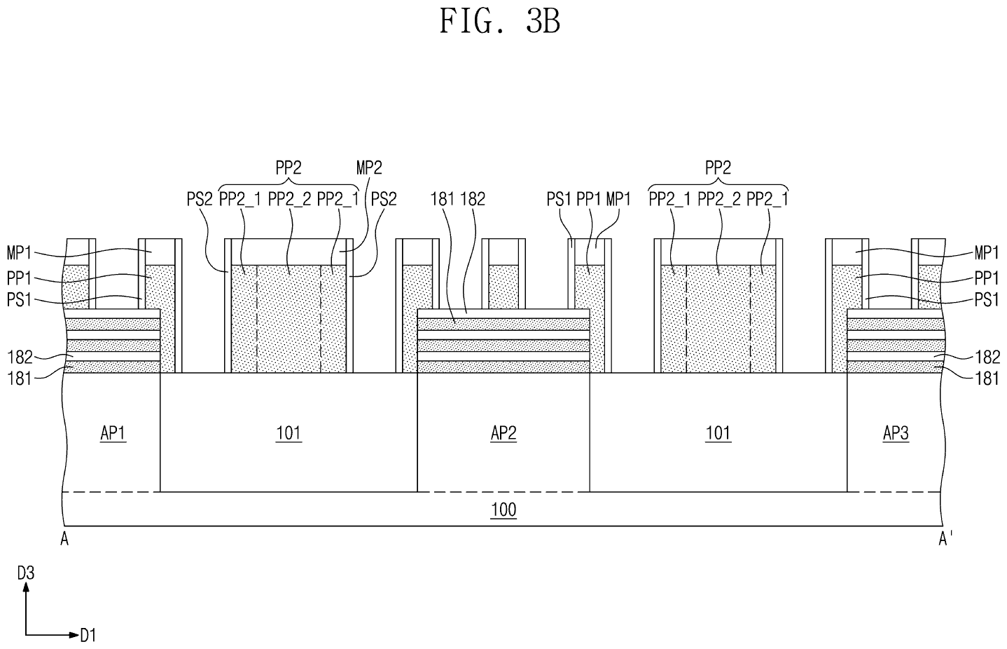

Referring to FIGS. 3A and 3B, first sacrificial patterns PP1, second sacrificial patterns PP2, first mask patterns MP1, and second mask patterns MP2 may be formed.

Forming the first sacrificial patterns PP1, the second sacrificial patterns PP2, the first mask patterns MP1, and the second mask patterns MP2 may include forming a preliminary pattern film, forming the first mask patterns MP1 and the second mask patterns MP2 on the preliminary pattern film, and patterning the preliminary pattern film by using the first mask patterns MP1 and the second mask patterns MP2 as an etching mask. The first sacrificial patterns PP1 and the second sacrificial patterns PP2 may be formed by patterning the preliminary pattern film by using the first mask patterns MP1 and the second mask patterns MP2.

The first and second sacrificial patterns PP1 and PP2 may include, for example, poly silicon. The first and second mask patterns MP1 and MP2 may include an insulating material.

The first sacrificial pattern PP1 may extend in the second direction D2. The first sacrificial pattern PP1 may overlap the first and fourth active patterns AP1 and AP4 in the third direction D3, overlap the second and fourth active patterns AP2 and AP4 in the third direction D3, and/or overlap the third and fourth active patterns AP3 and AP4 in the third direction D3.

The second sacrificial pattern PP2 may be disposed between the first and second active patterns AP1 and AP2 and/or between the second and third active patterns AP2 and AP3. The second sacrificial pattern PP2 may overlap the fourth active pattern AP4 in the third direction D3.

The second sacrificial pattern PP2 may include first portions PP2_1 extending in the second direction D2 and second portions PP2_2 extending in the first direction D1. The second portions PP2_2 of the second sacrificial pattern PP2 may connect the first portions PP2_1 to each other.

The first mask pattern MP1 may be disposed on the first sacrificial pattern PP1. The second mask pattern MP2 may be provided on the second sacrificial pattern PP2.

The second mask pattern MP2 may include first portions extending in the second direction D2 and second portions extending in the first direction D1. The second portions of the second mask pattern MP2 may connect the first portions to each other.

First preliminary spacers PS1 and second preliminary spacers PS2 may be formed. The first preliminary spacers PS1 and the second preliminary spacers PS2 may be simultaneously formed. The first preliminary spacers PS1 and the second preliminary spacers PS2 may include the same insulating material. The first preliminary spacer PS1 may be formed on sidewalls of the first sacrificial pattern PP1 and the first mask pattern MP1. The second preliminary spacer PS2 may be formed on sidewalls of the second sacrificial pattern PP2 and the second mask pattern MP2. A portion, of the second preliminary spacers PS2, surrounded by the second sacrificial pattern PP2 may be defined as the first inner spacer 142 (see FIG. 1D).

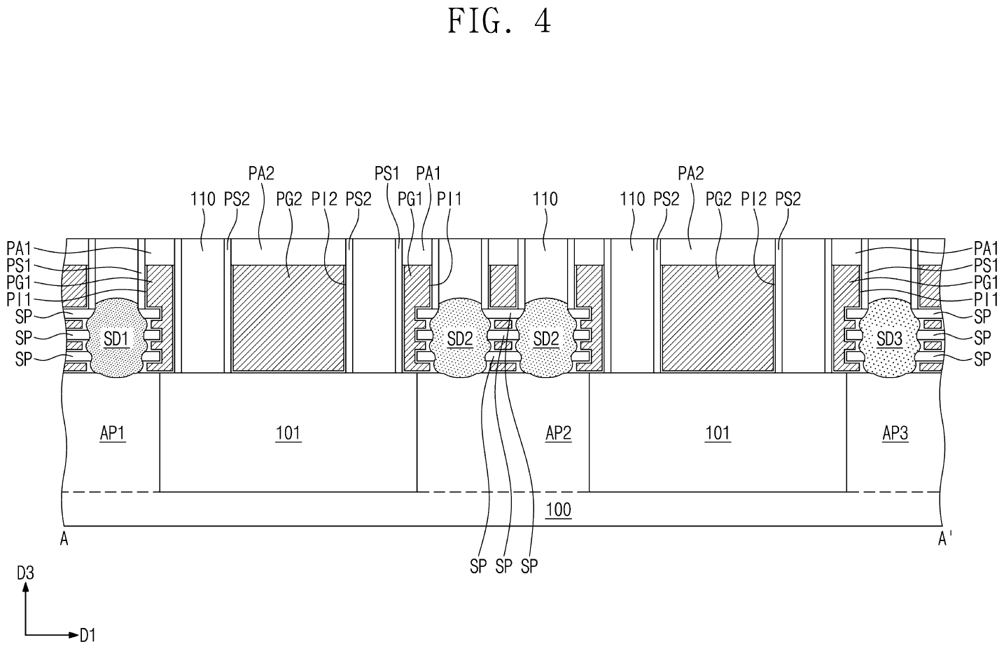

Referring to FIG. 4, the sacrificial films 181 and the semiconductor films 182 may be etched by using the first and second mask patterns MP1 and MP2 and the first and second preliminary spacers PS1 and PS2 as an etching mask. Semiconductor patterns SP may be formed by etching the semiconductor film 182. The semiconductor film 182 may be separated into the semiconductor patterns SP.

Source/drain patterns SD1, SD2, and SD3 may be formed. The source/drain patterns SD1, SD2, and SD3 may be formed through an epitaxial growth process in which the semiconductor patterns SP and the etched sacrificial films 181 are used as a seed for the growth process.

A first interlayer insulating layer 110 may be formed. The inner insulating film 111 (see FIG. 1D) may be formed simultaneously with the first interlayer insulating layer 110.

The sacrificial films 181, the first and second mask patterns MP1 and MP2, and the first and second sacrificial patterns PP1 and PP2 may be removed. First preliminary gate insulating films PI1, second preliminary gate insulating films PI2, first preliminary gate electrodes PG1, second preliminary gate electrodes PG2, first preliminary capping films PA1, and second preliminary capping films PA2 may be formed in empty spaces which are formed by removing the sacrificial films 181, the first and second mask patterns MP1 and MP2, and the first and second sacrificial patterns PP1 and PP2.

The first preliminary gate insulating film PI1, the first preliminary gate electrode PG1, and the first preliminary capping film PA1 may be formed in empty spaces which are formed by removing the sacrificial films 181, the first mask pattern MP1, and the first sacrificial pattern PP1. The second preliminary gate insulating film PI2, the second preliminary gate electrode PG2, and the second preliminary capping film PA2 may be formed in empty spaces which are formed by removing the sacrificial films 181, the second mask pattern MP2, and the second sacrificial pattern PP2.

The first and second preliminary gate insulating films PI1 and PI2 may include an insulating material. The first and second preliminary gate electrodes PG1 and PG2 may include a conductive material. The first and second preliminary capping films PA1 and PA2 may include an insulating material.

Referring to FIGS. 1A to 1G, the isolation insulating films IL may be formed. In a process of forming the isolation insulating films IL, the first and second preliminary gate insulating films PI1 and PI2 may be separated from each other by, for example, a patterning or etching process, and gate insulating films GI and the dummy insulating films 145 may be formed.

In a process of forming the isolation insulating films IL, the first and second preliminary gate electrodes PG1 and PG2 may be separated from each other by, for example, a patterning process, and the first and second gate electrodes GE1 and GE2, the connection lines CL, the first to sixth dummy lines DL1 to DL6, and the first and second dummy structures 130 and 160 may be formed.

In a process of forming the isolation insulating films IL, the first and second preliminary capping films PA1 and PA2 may be separated from each other by, for example, a patterning or etching process, and the gate capping patterns GP and the dummy capping patterns 150 may be formed.

In a process of forming the isolation insulating films IL, the first and second preliminary spacers PS1 and PS2 may be separated from each other by, for example, a patterning or etching process, and the gate spacers GS, the outer spacers 141, and the second and third inner spacers 143 and 144 may be formed.

The second interlayer insulating layer 120 may be formed. The active contacts AC and the gate contacts GC may be formed.

In a method for manufacturing a semiconductor device according to embodiments of the present inventive concept, an upper surface of the first interlayer insulating layer 110 and upper surfaces of the preliminary capping films PA1 and PA2 may be planarized in a process of forming the preliminary gate electrodes PG1 and PG2 and the preliminary capping films PA1 and PA2. Since the second preliminary spacer PS2, the second preliminary gate electrode PG2, and the second preliminary capping film PA2 are provided, a dishing phenomenon in a portion between the first and second active patterns AP1 and AP2 and a portion between the second and third active patterns AP2 and AP3 of the first interlayer insulating layer 110 may be prevented or suppressed in a process of planarizing the first interlayer insulating layer 110. Since the dishing phenomenon is prevented, stability of a subsequent process may be increased.

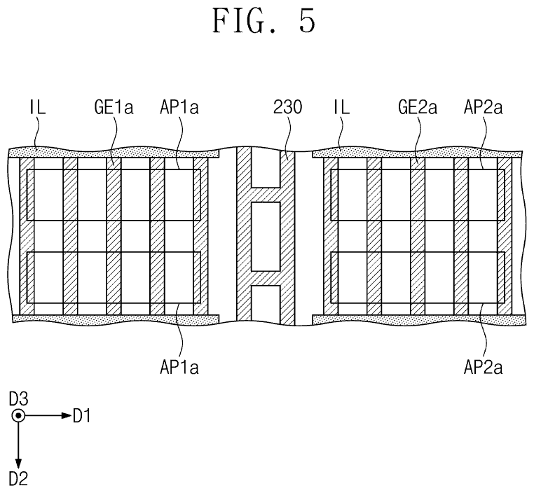

FIG. 5 is a plan view of a semiconductor device according to embodiments of the present inventive concept. The semiconductor device according to FIG. 5 may be similar to a semiconductor device according to FIGS. 1A to 1G except as described below. To the extent that the description of various elements are omitted, it may be assumed that these elements are at least similar to corresponding elements that have already been described

Referring to FIG. 5, the semiconductor device may include first active patterns AP1a and second active patterns AP2a. The first active pattern AP1a and the second active pattern AP2a may be spaced apart from each other in the first direction D1. The first active pattern AP1a and the second active pattern AP2a may be a cell active pattern.

First gate electrodes GE1a may be provided on the first active patterns AP1a. Second gate electrodes GE2a may be provided on the second active patterns AP2a. The first and second gate electrodes GE1a and GE2a may be a cell gate electrode.

A dummy structure 230 may be provided between the first and second active patterns AP1a and AP2a.

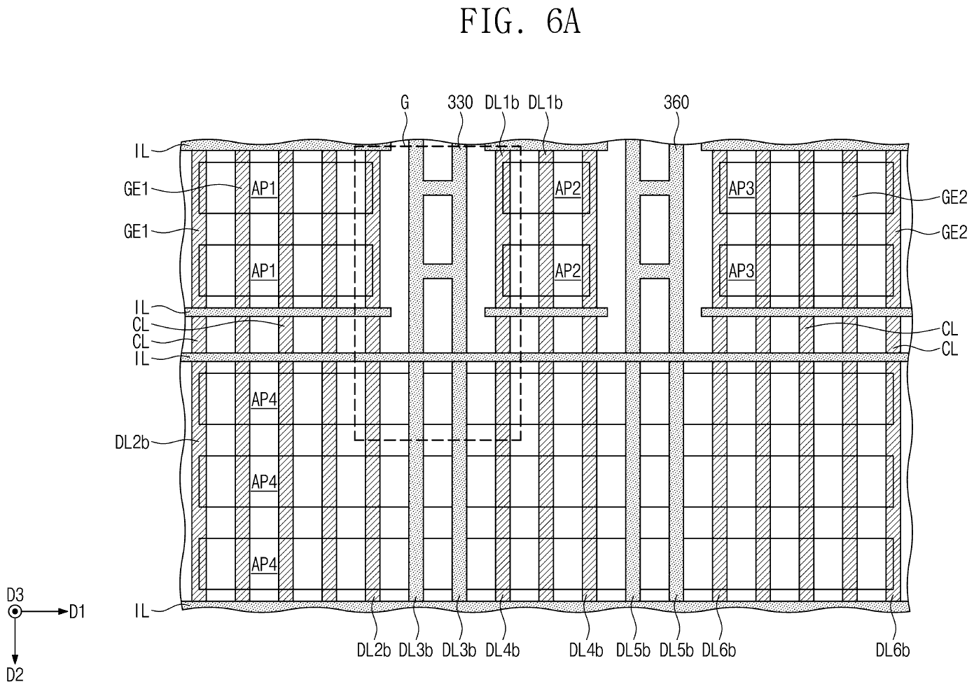

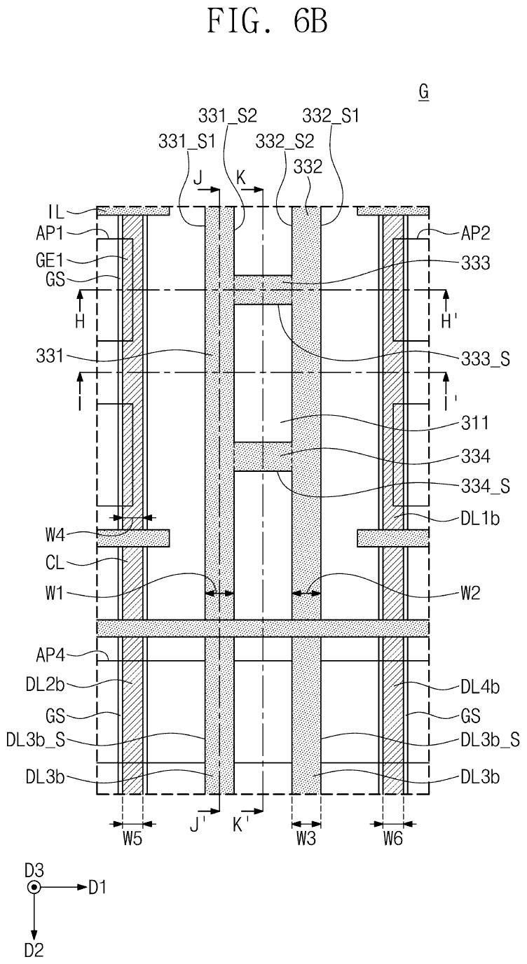

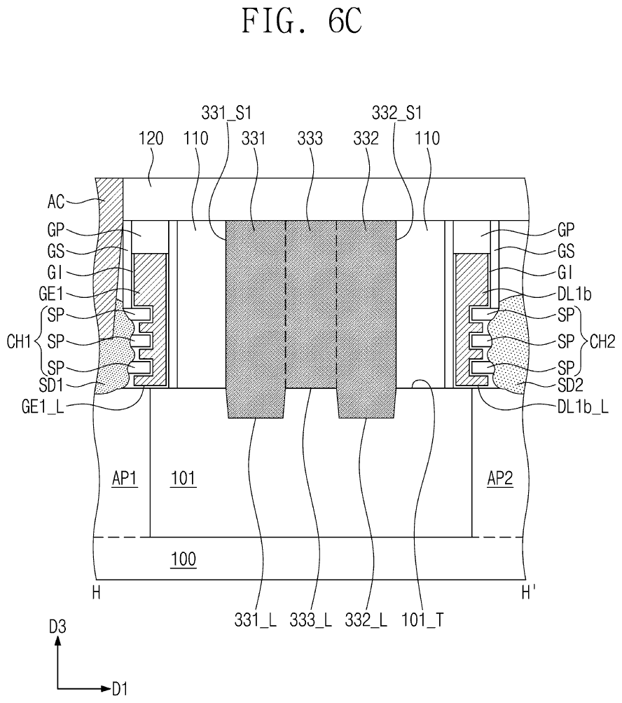

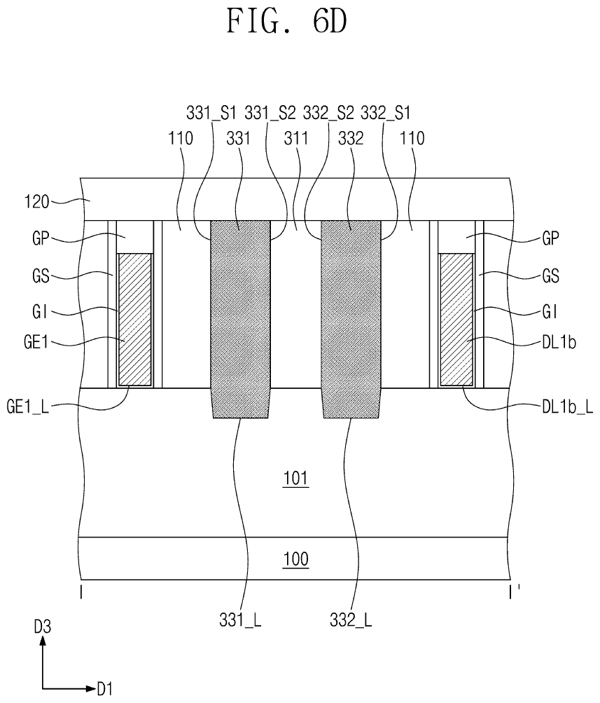

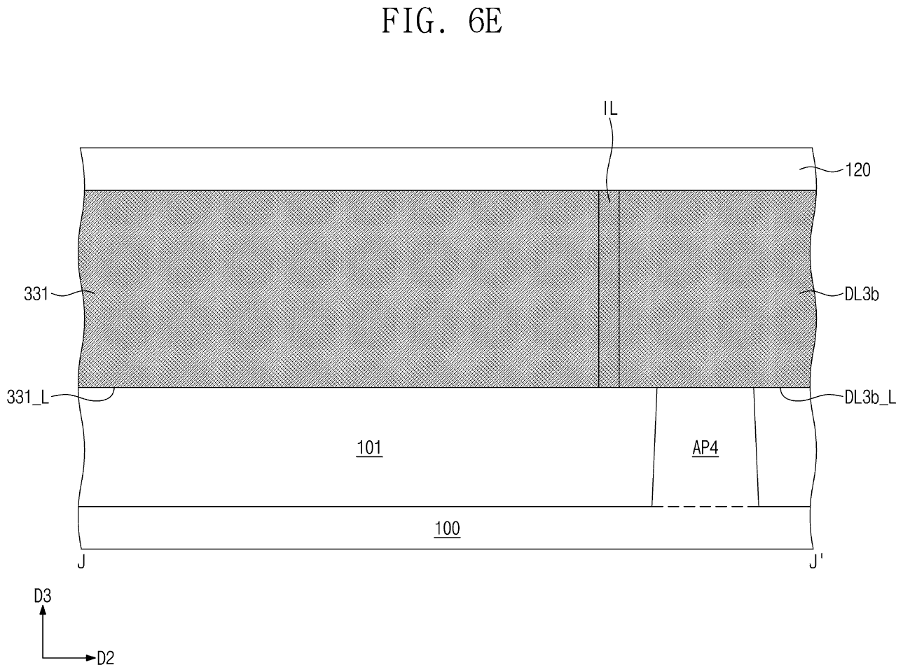

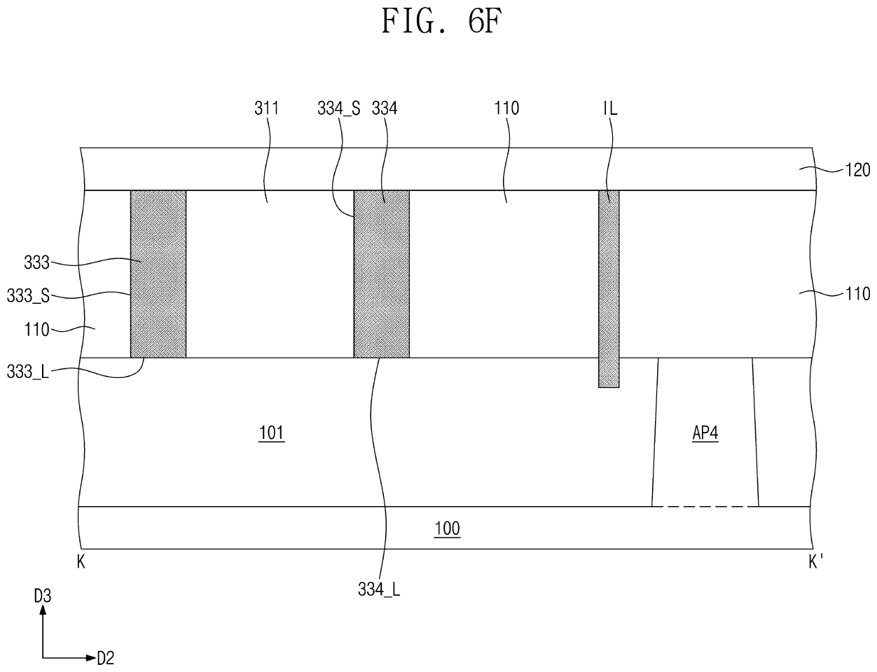

FIG. 6A is a plan view of a semiconductor device according to embodiments of the present inventive concept. FIG. 6B is an enlarged view of region G of FIG. 6A. FIG. 6C is a cross-sectional view taken along line H-H′ of FIG. 6B. FIG. 6D is a cross-sectional view taken along line I-I′ of FIG. 6B. FIG. 6E is a cross-sectional view taken along line J-J′ of FIG. 6B. FIG. 6F is a cross-sectional view taken along line K-K′ of FIG. 6B. A semiconductor device according to FIGS. 6A to 6F may be similar to a semiconductor device according to FIGS. 1A to 1G except as described below.

Referring to FIGS. 6A, 6B, 6C, 6D, 6E, and 6F, the semiconductor device may include first dummy lines DL1b, second dummy lines DL2b, third dummy lines DL3b, fourth dummy lines DL4b, fifth dummy lines DL5b, and sixth dummy lines DL6b.

The first dummy line DL1b may be provided on a second active pattern AP2. The second to sixth dummy lines DL2b, DL3b, DL4b, DL5b, and DL6b may be provided on a fourth active pattern AP4.

The first dummy line DL1b, the second dummy line DL2b, the fourth dummy line DL4b, and the sixth dummy line DL6b may include the same conductive material as first and second gate electrodes GE1 and GE2 and connection lines CL. Each of the first dummy line DL1b, the second dummy line DL2b, the fourth dummy line DL4b, and the sixth dummy line DL6b may be a dummy gate electrode.

The third and fifth dummy lines DL3b and DL5b may include an insulating material.

A first dummy structure 330 may be provided between first and second active patterns AP1 and AP2. A second dummy structure 360 may be provided between second and third active patterns AP2 and AP3. The first and second dummy structures 330 and 360 may include the same insulating material as the third and fifth dummy lines DL3b and DL5b. The first and second dummy structures 330 and 360 may be a diffusion prevention insulating structure. The third and fifth dummy lines DL3b and DL5b may be diffusion prevention insulating lines.

The first dummy structure 330 may include a first line portion 331, a second line portion 332, a first connection portion 333, and a second connection portion 334. Similar to the first dummy structure 330, the second dummy structure 360 may include a first line portion, a second line portion, a first connection portion, and a second connection portion.

The first line portion 331 may include a first sidewall 331_S1 and second sidewalls 331_S2. The second line portion 332 may include a first sidewall 332_S1 and second sidewalls 332_S2. The first sidewall 331_S1 of the first line portion 331 and a sidewall DL3b_S of the third dummy line DL3b may be parallel to the second direction D2. According to embodiments of the present inventive concept, the first sidewall 331_S1 of the first line portion 331 and the sidewall DL3b_S of the third dummy line DL3b may be arranged on a straight line extending in the second direction D2. The first sidewall 332_S1 of the second line portion 332 and the sidewall DL3b_S of the third dummy line DL3b may be parallel to the second direction D2. According to embodiments of the present inventive concept, the first sidewall 332_S1 of the second line portion 332 and the sidewall DL3b_S of the third dummy line DL3b may be arranged on a straight line extending in the second direction D2.

Each of sidewalls 333_S of the first connection portion 333 may be connected to a second sidewall 331_S2 of the first line portion 331 and a second sidewall 332_S2 of the second line portion 332. Each of sidewalls 334_S of the second connection portion 334 may be connected to a second sidewall 331_S2 of the first line portion 331 and a second sidewall 332_S2 of the second line portion 332.

An inner insulating film 311 surrounded by the first dummy structure 330 may be provided. The inner insulating film 311 may be in contact with each of the second sidewall 331_S2 of the first line portion 331, the second sidewall 332_S2 of the second line portion 332, the sidewall 333_S of the first connection portion 333, and the sidewall 334_S of the second connection portion 334.

A width W1 of the first line portion 331 in the first direction D1, a width W2 of the second line portion 332 in the first direction D1, and a width W3 of the third dummy line DL3b in the first direction D1 may be the same as one another.

Each of the width W1 of the first line portion 331 in the first direction D1, the width W2 of the second line portion 332 in the first direction D1, and the width W3 of the third dummy line DL3b in the first direction D1 may be greater than each of a width W4 of the first gate electrode GE1 in the first direction D1, a width W5 of the second dummy line DL2b in the first direction D1, and a width W6 of the first dummy line DL1b in the first direction D1.

A level of a lowermost portion 331_L of the first line portion 331, a level of a lowermost portion 332_L of the second line portion 332, a level of a lowermost portion DL3b_L of the third dummy line DL3b, and a level of a lowermost portion of the fifth dummy line DL5b may be lower than a level of a lowermost portion 333_L of the first connection portion 333, a level of a lowermost portion 334_L of the second connection portion 334, a level of a lowermost portion GE1_L of the first gate electrode GE1, a level of a lowermost portion of the second gate electrode GE2, a level of a lowermost portion DL1b_L of the first dummy line DL1b, a level of a lowermost portion of the second dummy line DL2b, a level of a lowermost portion of the fourth dummy line DL4b, a level of a lowermost portion of the sixth dummy line DL6b, and a level of an upper surface 101_T of an element isolation film 101. The lowermost portion 331_L of the first line portion 331 and the lowermost portion 332_L of the second line portion 332 may be disposed in the element isolation film 101.

Isolation insulating films IL may include an isolation insulating film IL which separates the first dummy structure 330 and the third dummy line DL3b and separates the second dummy structure 360 and the fifth dummy line DL5b.

A second interlayer insulating layer 120 may be disposed on upper surfaces of the first and second dummy structures 330 and 360. For example, the second interlayer insulating layer 120 may be in contact with upper surfaces of the first and second dummy structures 330 and 360.

In a semiconductor device according to embodiments of the present inventive concept, since the first and second dummy structures 330 and 360 and the third and fifth dummy lines DL3b and DL5b do not include a conductive material, a phenomenon in which capacitance is increased due to a conductive material may be prevented or suppressed.

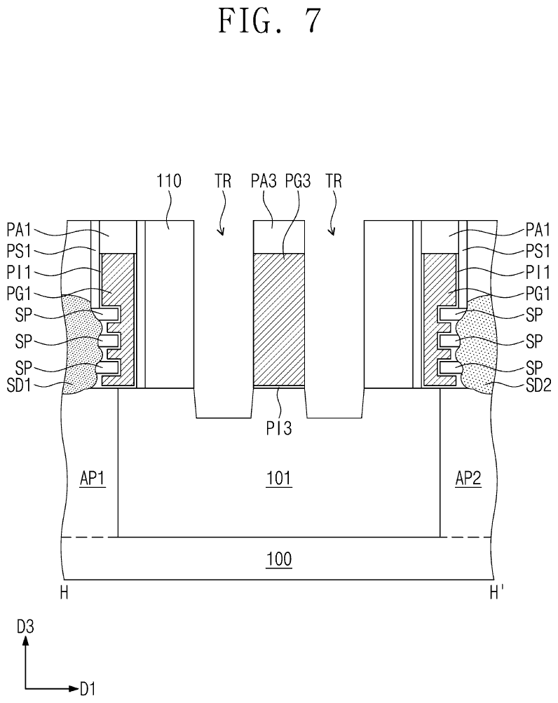

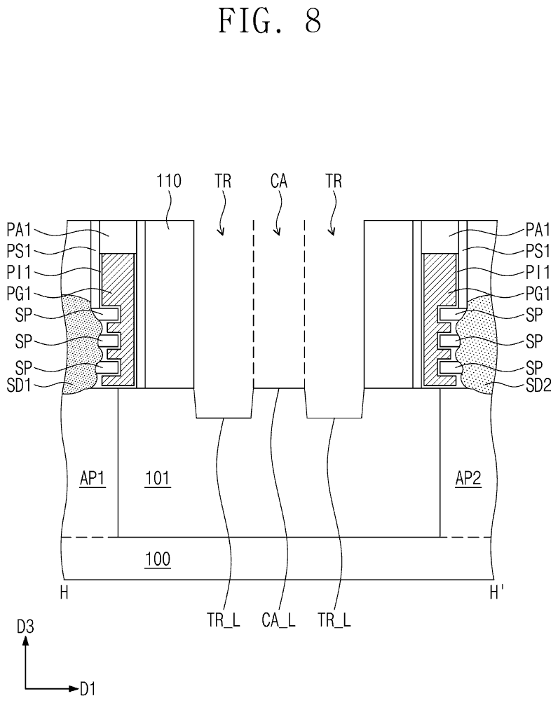

FIGS. 7 and 8 are cross-sectional views for describing a method for manufacturing a semiconductor device according to FIGS. 6A to 6F.

Similar to the descriptions made with reference to FIGS. 2A to 4, the active patterns AP1, AP2, AP3, and AP4, the element isolation film 101, the semiconductor patterns SP, the source/drain patterns SD1, SD2, and SD3, the first and second preliminary spacers PS1 and PS2, the first and second preliminary gate insulating films PI1 and PI2, the first and second preliminary gate electrodes PG1 and PG2, the first and second preliminary capping films PA1 and PA2, and the first interlayer insulating layer 110 may be formed.

Referring to FIG. 7, trenches TR may be formed. The trench TR may extend in the second direction D2 and the third direction D3 (e.g., the vertical direction). The trenches TR may be spaced apart from each other in the first direction D1. A space which is formed by etching the second preliminary capping film PA2, the second preliminary gate electrode PG2, the second preliminary gate insulating film PI2, and the second preliminary spacer PS2 may be defined as the trench TR.

A preliminary capping pattern PA3 may be formed by etching the second preliminary capping film PA2 (see, e.g., FIG. 4). A portion of the second preliminary capping film PA2 that remains after an etching process may be defined as the preliminary capping pattern PA3. A preliminary electrode pattern PG3 may be formed by etching the second preliminary gate electrode PG2. A portion of the second preliminary gate electrode PG2 that remains after an etching process may be defined as the preliminary electrode pattern PG3. A preliminary insulating pattern PI3 may be formed by etching the second preliminary gate insulating film PI2. A portion of the second preliminary gate insulating film PI2 that remains after an etching process may be defined as the preliminary insulating pattern PI3.

The preliminary capping pattern PA3, the preliminary electrode pattern PG3, and the preliminary insulating pattern PI3 may be arranged between the trenches TR (e.g., adjacent trenches TR).

Referring to FIG. 8, the preliminary capping pattern PA3, the preliminary electrode pattern PG3, and the preliminary insulating pattern PI3 may be removed. Removing the preliminary capping pattern PA3, the preliminary electrode pattern PG3, and the preliminary insulating pattern PI3 may include etching the preliminary capping pattern PA3, the preliminary electrode pattern PG3, and the preliminary insulating pattern PI3 through the trenches TR.

An empty space which is formed by removing the preliminary capping pattern PA3, the preliminary electrode pattern PG3, and the preliminary insulating pattern PI3 may be defined as a cavity CA. The cavity CA may connect the trenches TR to each other.

A level of a lowermost portion TR_L of the trench TR may be lower than a level of a lowermost portion CA_L of the cavity CA.

Referring to FIGS. 6A to 6F, the first dummy structure 330, the second dummy structure 360, the third dummy line DL3b, the fifth dummy line DL5b, and the isolation insulating film IL may be formed. Forming the first dummy structure 330, the second dummy structure 360, the third dummy line DL3b, the fifth dummy line DL5b, and the isolation insulating film IL may include forming preliminary insulating structures that fill the trenches TR and cavities CA, and separating the preliminary insulating structures from each other by forming the isolation insulating film IL. The preliminary insulating structures may be separated from each other, and the first dummy structure 330, the second dummy structure 360, the third dummy line DL3b, and the fifth dummy line DL5b may be formed.

According to embodiments of the present inventive concept, the isolation insulating films IL may be formed before the trenches TR.

The first line portion 331 and the second line portion 332 of the first dummy structure 330 may be each formed in the trench TR. Each of the first connection portion 333 and the second connection portion 334 of the first dummy structure 330 may be formed in the cavity CA.

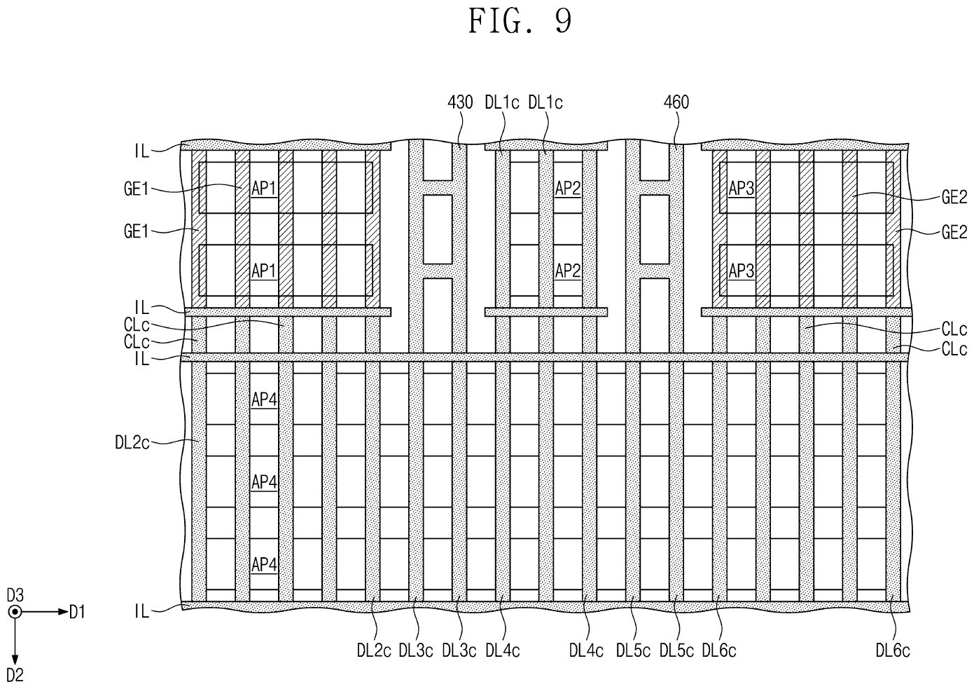

FIG. 9 is a plan view of a semiconductor device according to embodiments of the present inventive concept. The semiconductor device according to FIG. 9 may be similar to a semiconductor device according to FIGS. 6A to 6F except as described below.

Referring to FIG. 9, a first dummy structure 430 and a second dummy structure 460 may include an insulating material. The first and second dummy structures 430 and 460 may be a diffusion prevention insulating structure.

A first dummy line DL1c, a second dummy line DL2c, a third dummy line DL3c, a fourth dummy line DL4c, a fifth dummy line DL5c, a sixth dummy line DL6c and a connection line CLc may include the same insulating material as the first dummy structure 430 and the second dummy structure 460. The first to sixth dummy lines DL1c, DL2c, DL3c, DL4c, DL5c, and DL6c and the connection line CLc may be diffusion prevention insulating lines.

According to embodiments of the present inventive concept, at least one among the first and second dummy structures 430 and 460, the first to sixth dummy lines DL1c, DL2c, DL3c, DL4c, DL5c, and DL6c, and the connection line CLc may include the same conductive material as gate electrodes GE1 and GE2.

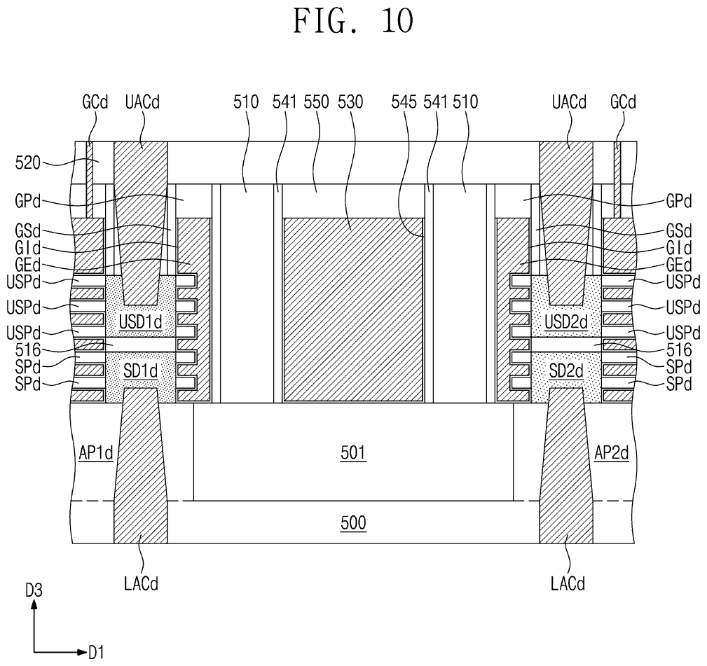

FIG. 10 is a cross-sectional view of a semiconductor device according to embodiments of the present inventive concept. The semiconductor device according to FIG. 10 may be similar to a semiconductor device according to FIGS. 1A to 1G except as described below. To the extent that the description of various elements omitted, it may be assumed that these elements are at least similar to corresponding elements that have already been described

Referring to FIG. 10, the semiconductor device may include a substrate 500. The substrate 500 may include a first active pattern AP1d and a second active pattern AP2d. An element isolation film 501 surrounding the first and second active patterns AP1d and AP2d may be provided.

Upper semiconductor patterns USPd and semiconductor patterns SPd overlapping the active patterns AP1d and AP2d in the third direction D3 may be provided. The upper semiconductor patterns USPd may be arranged at a higher level than the semiconductor patterns SPd.

Interposed insulating patterns 516 may be provided. The interposed insulating pattern 516 may be disposed between the semiconductor pattern SPd and the upper semiconductor pattern USPd. The interposed insulating pattern 516 may include an insulating material.

A first source/drain pattern SD1d may be provided on the first active pattern AP1d. A second source/drain pattern SD2d may be provided on the second active pattern AP2d.

A first upper source/drain pattern USD1d, which overlaps the first source/drain pattern SD1d in the third direction D3, and a second upper source/drain pattern USD2d, which overlaps the second source/drain pattern SD2d in the third direction D3, may be provided. The upper source/drain patterns USD1d and USD2d may be an epitaxial pattern which is formed through a selective epitaxial growth (SEG) process. The upper source/drain patterns USD1d and USD2d may be in contact with the upper semiconductor patterns USPd.

Gate electrodes GEd may be provided. The gate electrodes GEd may surround the semiconductor patterns SPd and the upper semiconductor patterns USPd.

Gate insulating films GId may be provided. The gate electrode GEd may be spaced apart from the semiconductor patterns SPd and the upper semiconductor patterns USPd by the gate insulating film GId. Gate spacers GSd may be provided on two sides of the gate electrode GEd. A gate capping pattern GPd may be provided on the gate electrode GEd.

A dummy structure 530 may be provided. The dummy structure 530 may be provided between the first active pattern AP1d and the second active pattern AP2d. The dummy structure 530 may be provided on the element isolation film 501. The dummy structure 530 may include the same conductive material as the gate electrode GEd. The dummy structure 530 may be electrically floated. The dummy structure 530 may include a first line portion and a second line portion extending in the second direction D2, and a first connection portion and a second connection portion connecting the first line portion and the second line portion to each other.

A pair of outer spacers 541 may be disposed on two sides of the dummy structure 530. Inner spacers may be disposed in the dummy structure 530. A dummy insulating film 545 may be disposed on the dummy structure 530. For example, the dummy insulating film 545 may be in contact with the dummy structure 530 A dummy capping pattern 550 may be provided on the dummy structure 530.

A first interlayer insulating layer 510 may be provided. A second interlayer insulating layer 520 may be provided on the first interlayer insulating layer 510 and the dummy capping pattern 550.

Upper active contacts UACd may be provided. The upper active contacts UACd may be in contact with the upper source/drain patterns USD1d and USD2d. Lower active contacts LACd may be provided. The lower active contacts LACd may be in contact with the source/drain patterns SD1d and SD2d. The lower active contacts LACd may penetrate the substrate 500 and the active patterns AP1d and AP2d. A gate contact GCd may be provided. The gate contact GCd may contact the gate electrodes GEd.

In a semiconductor device according to embodiments of the present inventive concept, since a dummy structure includes connection portions, a leaning phenomenon of the dummy structure may be prevented or suppressed in a process of forming the dummy structure.

In a method for manufacturing a semiconductor device according to embodiments of the present inventive concept, a dishing phenomenon in an interlayer insulating layer may be prevented or suppressed, and stability of a subsequent process may be increased.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor device comprising:
a first active pattern;
a first source/drain pattern disposed on the first active pattern;
a second active pattern spaced apart from the first active pattern in a first direction;
a second source/drain pattern disposed on the second active pattern;
a gate electrode overlapping the first active pattern and extending in a second direction intersecting the first direction; and
a dummy structure disposed between the first active pattern and the second active pattern and between the first source/drain pattern and the second source/drain pattern,
wherein the dummy structure includes:
a first line portion extending in the second direction;
a second line portion extending in the second direction and spaced apart from the first line portion in the first direction; and
a first connection portion connecting the first line portion and the second line portion to each other.

2. The semiconductor device of claim 1, wherein the dummy structure further comprises a second connection portion connecting the first line portion and the second line portion to each other, and
the first connection portion and the second connection portion are spaced apart from each other in the second direction.

3. The semiconductor device of claim 2, further comprising an inner spacer surrounded by the first line portion, the second line portion, the first connection portion, and the second connection portion.

4. The semiconductor device of claim 3, further comprising an inner insulating film surrounded by the inner spacer.

5. The semiconductor device of claim 3, wherein the inner spacer is disposed on a sidewall of the first line portion, a sidewall of the second line portion, a sidewall of the first connection portion, and a sidewall of the second connection portion,
the sidewall of the first connection portion is connected to the sidewall of the first line portion and the sidewall of the second line portion, and
the sidewall of the second connection portion is connected to the sidewall of the first line portion and the sidewall of the second line portion.

6. The semiconductor device of claim 1, wherein a level of a lowermost portion of the first line portion and a level of a lowermost portion of the second line portion are lower than a level of a lowermost portion of the first connection portion.

7. The semiconductor device of claim 6, further comprising an element isolation film at least partially surrounding the first active pattern and the second active pattern,
wherein a level of the lowermost portion of the first line portion and a level of the lowermost portion of the second line portion are lower than a level of an upper surface of the element isolation film.

8. The semiconductor device of claim 1, wherein each of a width of the first line portion in the first direction and a width of the second line portion in the first direction is greater than a width of the gate electrode in the first direction.

9. A semiconductor device comprising:
a first active pattern;
a second active pattern spaced apart from the first active pattern in a first direction;
a dummy structure disposed between the first active pattern and the second active pattern;
a gate electrode disposed on the first active pattern and extending in a second direction intersecting the first direction;
a dummy active pattern spaced apart from the first active pattern and the second active pattern in the second direction; and
a first dummy line and a second dummy line disposed on the dummy active pattern and extending in the second direction,
wherein the first dummy line overlaps the gate electrode in the second direction, and
the second dummy line overlaps the dummy structure in the second direction.

10. The semiconductor device of claim 9, wherein a sidewall of the gate electrode and a sidewall of the first dummy line are aligned with each other in the second direction.

11. The semiconductor device of claim 9, wherein the first dummy line comprises a conductive material and is electrically floated.

12. The semiconductor device of claim 9, further comprising:
a connection line disposed between the first dummy line and the gate electrode;
a first isolation insulating film disposed between the first dummy line and the connection line; and
a second isolation insulating film disposed between the gate electrode and the connection line,
wherein the connection line overlaps the first dummy line and the gate electrode in the second direction.

13. The semiconductor device of claim 9, wherein the dummy structure comprises:
a first line portion extending in the second direction;
a second line portion extending in the second direction and spaced apart from the first line portion in the first direction; and
a connection portion connecting the first line portion and the second line portion to each other,
wherein the second dummy line overlaps the first line portion in the second direction.

14. The semiconductor device of claim 13, wherein the dummy structure and the second dummy line comprise an insulating material, and
a level of a lowermost portion of the first line portion, a level of a lowermost portion of the second line portion, and a level of a lowermost portion of the second dummy line are lower than each of a level of a lowermost portion of the connection portion and a level of a lowermost portion of the gate electrode.

15. The semiconductor device of claim 9, wherein the dummy structure and the second dummy line comprise a conductive material and are electrically floated.

16. The semiconductor device of claim 9, further comprising:
a third dummy line disposed on the second active pattern and extending in the second direction; and
a fourth dummy line disposed on the dummy active pattern and extending in the second direction,
wherein the third dummy line and the fourth dummy line overlap each other in the second direction.

17. The semiconductor device of claim 16, wherein a distance between a center of the gate electrode and a center of the third dummy line is a multiple of a distance between a center of the first dummy line and a center of the second dummy line.

18. A semiconductor device comprising:
a first active pattern;
a first source/drain pattern disposed on the first active pattern;
a second active pattern spaced apart from the first active pattern in a first direction;
a second source/drain pattern disposed on the second active pattern;
a dummy active pattern spaced apart from the first active pattern and the second active pattern in a second direction, wherein the second direction intersects the first direction;
a dummy structure disposed between the first active pattern and the second active pattern, and between the first source/drain pattern and the second source/drain pattern;
a gate electrode disposed on the first active pattern and extending in the second direction; and
a first dummy line and a second dummy line disposed on the dummy active pattern and extending in the second direction,
wherein the dummy structure includes:
a first line portion extending in the second direction;
a second line portion extending in the second direction and spaced apart from the first line portion in the first direction; and
a connection portion connecting the first line portion and the second line portion to each other,
wherein the first dummy line overlaps the gate electrode in the second direction, and
the second dummy line overlaps the first line portion in the second direction.

19. The semiconductor device of claim 18, wherein the dummy structure comprises an insulating material, and
a level of a lowermost portion of the first line portion and a level of a lowermost portion of the second line portion are lower than each of a level of a lowermost portion of the connection portion and a level of a lowermost portion of the gate electrode.

20. The semiconductor device of claim 19, wherein the first dummy line and the second dummy line comprise an insulating material, and
a level of a lowermost portion of the first dummy line and a level of a lowermost portion of the second dummy line are lower than each of a level of the lowermost portion of the connection portion and a level of the lowermost portion of the gate electrode.
